(19) United States
(12) Patent Application Publication
(10) Pub. No.: US 2024/0395552 A1
(43) Pub. Date: Nov. 28, 2024

(54) METHOD OF FORMING MASK PATTERN INCLUDING SURFACE ENHANCEMENT LAYER AND METHOD OF FORMING SEMICONDUCTOR DEVICE USING THE SAME

(71) Applicant: SK hynix Inc., Gyeonggi-do (KR)

(72) Inventor: Jin Woong KIM, Gyeonggi-do (KR)

(21) Appl. No.: 18/489,001

(22) Filed: Oct. 18, 2023

(30) Foreign Application Priority Data
May 23, 2023 (KR) 10-2023-0066040

(51) Int. Cl. H01L 21/033; H01L 21/3213; H01L 21/762

(52) U.S. Cl. CPC H01L 21/0332; H01L 21/32139; H01L 21/76224

(57) ABSTRACT

A method of forming a mask pattern may include forming a sacrificial mask pattern on a substrate. A plurality of upper mask patterns may be formed on side surfaces of the sacrificial mask pattern. Each of the plurality of upper mask patterns may include a surface enhancement layer and an upper mask layer. The upper mask layer may be formed between the surface enhancement layer and the sacrificial mask pattern. By removing the sacrificial mask pattern, the plurality of upper mask patterns may be exposed.

### CROSS-REFERENCE TO RELATED APPLICATION

The present application claims priority under 35 U.S.C. § 119 (a) to Korean Patent Application No. 10-2023-0066040 filed on May 23, 2023, which is incorporated herein by reference in its entirety.

### BACKGROUND

### 1. Technical Field

Various embodiments of the present disclosure generally relate to a method of forming a mask pattern including a surface enhancement layer, a method of forming a semiconductor device using the same, and a related semiconductor device.

### 2. Related Art

In order to cope with high integration of a semiconductor device, a spacer patterning technology has been attempted. The spacer patterning technology shows an advantageous effect in implementing fine patterns while overcoming technical limitations of photoresist patterning technology. Meanwhile, a spacer mask used in the spacer patterning technology is vulnerable to a defect such as leaning due to miniaturization of patterns and an increase in aspect ratio. The leaning of the spacer mask makes subsequent processes difficult.

### SUMMARY

Various embodiments of the present disclosure are directed to providing a method of forming a mask pattern capable of preventing leaning, a method of forming a semiconductor device using the same, and a related semiconductor device.

A method of forming a mask pattern according to an embodiment of the present disclosure may include forming a sacrificial mask pattern on a substrate. A plurality of upper mask patterns may be formed on side surfaces of the sacrificial mask pattern. Each of the plurality of upper mask patterns may include a surface enhancement layer and an upper mask layer. The upper mask layer may be formed between the surface enhancement layer and the sacrificial mask pattern. By removing the sacrificial mask pattern, the plurality of upper mask patterns may be exposed.

A method of forming a semiconductor device according to an embodiment of the present disclosure may include forming a hard mask layer on a substrate. A sacrificial mask pattern may be formed on the hard mask layer. A plurality of upper mask patterns may be formed on side surfaces of the sacrificial mask pattern. Each of the plurality of upper mask patterns may include a surface enhancement layer and an upper mask layer between the surface enhancement layer and the sacrificial mask pattern. By removing the sacrificial mask pattern, the plurality of upper mask patterns may be exposed. A plurality of hard mask patterns may be formed by partially removing the hard mask layer using the plurality of upper mask patterns as an etch mask. A plurality of trenches which define a plurality of semiconductor patterns may be formed in the substrate using the plurality of hard mask patterns as an etch mask. An isolation layer may be formed in the plurality of trenches.

A method of forming a semiconductor device according to an embodiment of the present disclosure may include forming a wiring layer on a substrate. A hard mask layer may be formed on the wiring layer. A sacrificial mask pattern may be formed on the hard mask layer.

A plurality of upper mask patterns may be formed on side surfaces of the sacrificial mask pattern. Each of the plurality of upper mask patterns may include a surface enhancement layer and an upper mask layer between the surface enhancement layer and the sacrificial mask pattern. By removing the sacrificial mask pattern, the plurality of upper mask patterns may be exposed. A plurality of hard mask patterns may be formed by partially removing the hard mask layer using the plurality of upper mask patterns as an etch mask. A plurality of wiring patterns may be formed by partially removing the wiring layer using the plurality of hard mask patterns as an etch mask.

According to the embodiments of the present disclosure, a surface enhancement layer may be formed on the surface of an upper mask layer. The surface enhancement layer may play the role of preventing leaning of upper mask patterns while processes of forming the upper mask patterns, removing sacrificial mask patterns and forming hard mask patterns are performed. A method of forming a semiconductor device that is advantageous for high integration and has high mass production efficiency may be provided.

### BRIEF DESCRIPTION OF THE DRAWINGS

FIG. 1 is a flowchart for explaining a method of forming a semiconductor device according to an embodiment of the present disclosure.

FIGS. 2 to 9 are cross-sectional views for explaining the method of forming a semiconductor device according to the embodiment of the present disclosure.

FIG. 10 is a flowchart for explaining a method of forming a semiconductor device according to an embodiment of the present disclosure.

FIGS. 11 to 18 are cross-sectional views for explaining the method of forming a semiconductor device according to the embodiment of the present disclosure.

### DETAILED DESCRIPTION

Hereinafter, embodiments of the present disclosure are described in detail with reference to the accompanying drawings.

Throughout the specification, reference to “an embodiment,” “another embodiment” or the like is not necessarily to only one embodiment, and different references to any such phrase are not necessarily limited to the same embodiment(s). The term “embodiments” when used herein does not necessarily refer to all embodiments.

Various embodiments of the present invention are described below in more detail with reference to the accompanying drawings. However, the present invention may be embodied in different forms and variations, and should not be construed as being limited to the embodiments set forth herein. Rather, the described embodiments are provided so that this disclosure will be thorough and complete, and will fully convey the present invention to those skilled in the art to which this invention pertains. Throughout this disclosure, like reference numerals refer to like parts throughout the various figures and embodiments of the present invention.

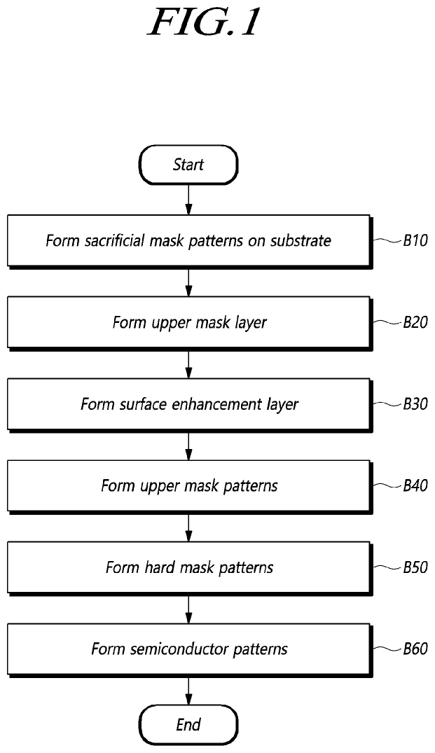

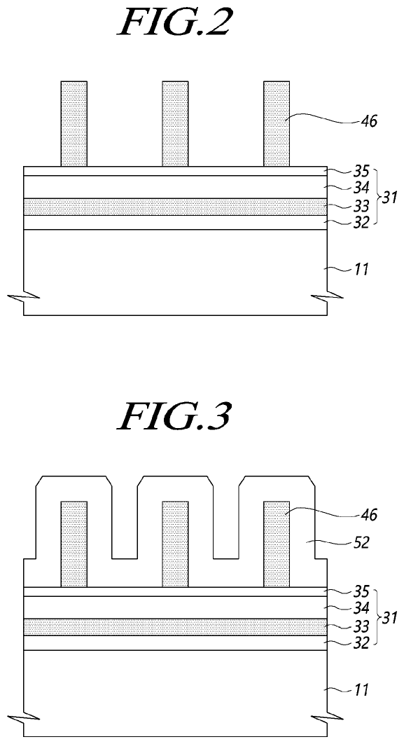

FIG. 1 is a flowchart for explaining a method of forming a semiconductor device according to an embodiment of the present disclosure, and FIGS. 2 to 9 are cross-sectional views for explaining the method of forming a semiconductor device according to the embodiment of the present disclosure.

Referring to FIG. 1, the method of forming a semiconductor device according to the embodiment of the present disclosure may include forming sacrificial mask patterns on a substrate (B10), forming an upper mask layer (B20), forming a surface enhancement layer (B30), forming upper mask patterns (B40), forming hard mask patterns (B50), and forming semiconductor patterns (B60).

Referring to FIGS. 1 and 2, a hard mask layer 31 may be formed on a substrate 11. A plurality of sacrificial mask patterns 46 may be formed on the substrate 11 on which the hard mask layer 31 is formed (B10).

The substrate 11 may include a semiconductor substrate such as a silicon wafer or a silicon on insulator (SOI) wafer. The substrate 11 may include a III-V group semiconductor substrate, for example, a compound semiconductor substrate such as GaAs. The substrate 11 may include monocrystalline silicon, polysilicon, amorphous silicon, monocrystalline silicon germanium, polycrystalline silicon germanium, carbon-doped silicon, or a combination thereof.

The hard mask layer 31 may cover the whole substrate 11. The hard mask layer 31 may include a single layer or a multilayer. In an embodiment, the hard mask layer 31 may include first to fourth layers 32, 33, 34 and 35 which are sequentially stacked on the substrate 11. For example, the first layer 32 may include silicon oxide, the second layer 33 may include polysilicon, the third layer 34 may include amorphous carbon, and the fourth layer 35 may include silicon oxynitride (SiON).

The first to fourth layers 32, 33, 34 and 35 may have different thicknesses, respectively. For example, the fourth layer 35 may have a thickness lesser than each of the second layer 33 and the third layer 34. In an embodiment, the fourth layer 35 may serve as an anti-reflective coating layer. Some of the first to fourth layers 32, 33, 34 and 35 may be selectively omitted.

The plurality of sacrificial mask patterns 46 may be formed by performing a lithography process. The plurality of sacrificial mask patterns 46 may include a photoresist or a carbon-containing composition. In an embodiment, the plurality of sacrificial mask patterns 46 may include photoresist patterns. The plurality of sacrificial mask patterns 46 may directly contact the upper surface of the hard mask layer 31. The fourth layer 35 may be exposed between the plurality of sacrificial mask patterns 46.

Referring to FIGS. 1 and 3, an upper mask layer 52 may be formed on the substrate 11 on which the plurality of sacrificial mask patterns 46 is formed (B20). The upper mask layer 52 may conformally cover the substrate 11 on which the plurality of sacrificial mask patterns 46 is formed. The upper mask layer 52 may cover the upper and side surfaces of the plurality of sacrificial mask patterns 46. The upper mask layer 52 may cover the hard mask layer 31 between the plurality of sacrificial mask patterns 46. The upper mask layer 52 may be formed by performing a low temperature deposition process, such as, an oxide deposition process performed at a temperature of 50° C. to 100° C. and an atomic layer deposition process performed at a temperature of 50° C. to 100° C. The upper mask layer 52 may include silicon oxide.

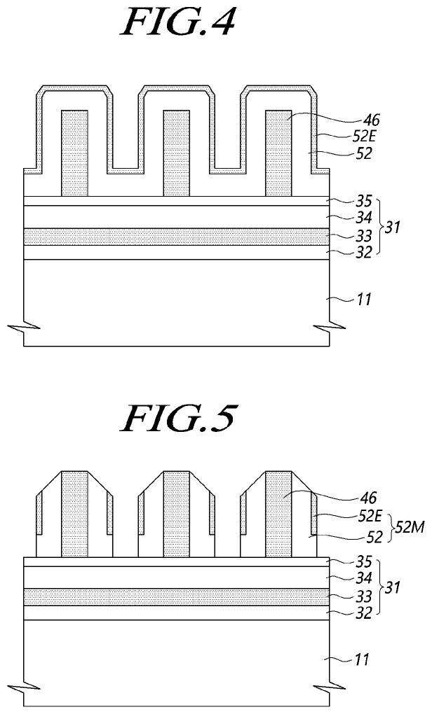

Referring to FIGS. 1 and 4, a surface enhancement layer 52E may be formed on the surface of the upper mask layer 52 (B30). The surface enhancement layer 52E may be formed to have a designed depth from the surface of the upper mask layer 52. The upper mask layer 52 may be disposed between the plurality of sacrificial mask patterns 46 and the surface enhancement layer 52E, and may be disposed between the hard mask layer 31 and the surface enhancement layer 52E. The surface enhancement layer 52E may have a lesser thickness than the upper mask layer 52. The surface enhancement layer 52E may have a higher hardness than the upper mask layer 52. The surface enhancement layer 52E may have a higher density than the upper mask layer 52. The surface enhancement layer 52E may be formed by using a rapid thermal annealing (RTA) process, a plasma treatment process or a combination thereof.

In an embodiment, the RTA process for forming the surface enhancement layer 52E may be performed at a temperature of 900° C. to 1100° C. for 0.001 second to 1 second. The RTA process for forming the surface enhancement layer 52E may be performed in an atmosphere in which helium gas, argon gas, nitrogen gas or a combination thereof is supplied.

Referring to FIGS. 1 and 5, by partially removing the surface enhancement layer 52E and the upper mask layer 52, a plurality of upper mask patterns 52M may be formed (B40). The plurality of upper mask patterns 52M may be formed by performing an anisotropic etching process of etching the surface enhancement layer 52E and the upper mask layer 52 until the upper surfaces of the plurality of sacrificial mask patterns 46 are exposed. In an embodiment, the hard mask layer 31 may be exposed between the plurality of upper mask patterns 52M.

The plurality of upper mask patterns 52M may be formed on the side surfaces (i.e., sidewalls), respectively, of the plurality of sacrificial mask patterns 46. The lower surface of each of the plurality of sacrificial mask patterns 46 and the plurality of upper mask patterns 52M may contact the upper surface of the hard mask layer 31. Each of the plurality of upper mask patterns 52M may include the surface enhancement layer 52E and the upper mask layer 52. The upper mask layer 52 may be remained on the side surfaces of the plurality of sacrificial mask patterns 46. The upper mask layer 52 may be interposed between the surface enhancement layer 52E and the hard mask layer 31. The upper mask layer 52 may contact the lower surface of the surface enhancement layer 52E and the upper surface of the hard mask layer 31.

The surface enhancement layer 52E may be remained on the side surface of the upper mask layer 52. The lowermost end of the surface enhancement layer 52E may be formed at a level higher than the upper surface of the hard mask layer 31. The lower surface of the surface enhancement layer 52E may be formed at a level higher than 20) the lowermost end of the upper mask layer 52. The lower surface of the surface enhancement layer 52E may contact the upper mask layer 52. The lowermost end of the surface enhancement layer 52E may be formed at a level higher than the lowermost ends of the plurality of sacrificial mask patterns 46.

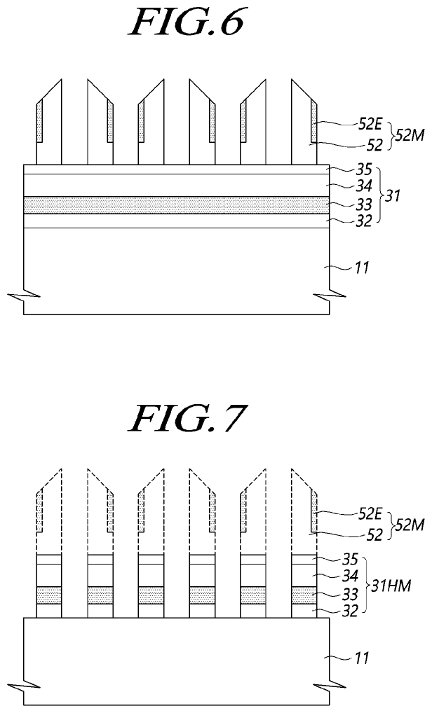

Referring to FIGS. 1 and 6, by removing the plurality of sacrificial mask patterns 46, the upper surface of the hard mask layer 31 may be exposed between the plurality of upper mask patterns 52M. The plurality of sacrificial mask patterns 46 may be removed by performing an ashing process.

Referring to FIGS. 1 and 7, by partially removing the hard mask layer 31, a plurality of hard mask patterns 31HM may be formed (B50). The plurality of hard mask patterns 31HM may be formed by performing an anisotropic etching process using the plurality of upper mask patterns 52M as an etch mask. While the anisotropic etching process is performed, the plurality of upper mask patterns 52M may be partially or entirely removed. The side surfaces of the plurality of hard mask patterns 31HM may be vertically aligned with the side surfaces of the plurality of upper mask patterns 52M.

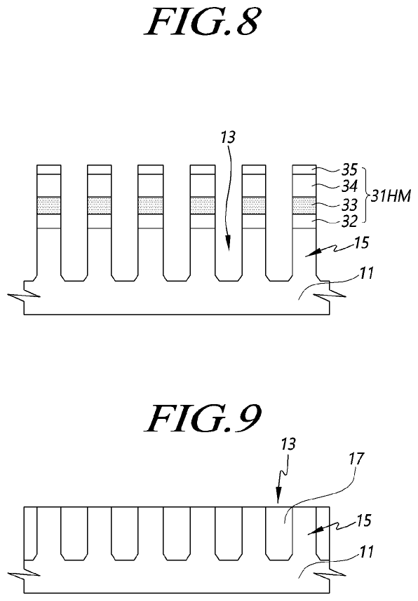

Referring to FIGS. 1 and 8, by using the plurality of hard mask patterns 31HM as an etch mask, a plurality of trenches 13 which define (i.e., delimit) a plurality of semiconductor patterns 15 may be formed in the substrate 11 (B60). The plurality of trenches 13 may be formed by performing an anisotropic etching process, a directional etching process, an isotropic etching process or a combination thereof.

Referring to FIGS. 1 and 9, an isolation layer 17 may be formed in the plurality of trenches 13. The plurality of hard mask patterns 31HM may be removed. The isolation layer 17 may include at least two selected from the group consisting of Si, O, N, B and C. In an embodiment, the isolation layer 17 may include an insulating material such as silicon oxide, silicon nitride, silicon oxynitride or a combination thereof. The isolation layer 17 may play the role of insulating the plurality of semiconductor patterns 15. The isolation layer 17 may be formed by performing a chemical-mechanical polishing (CMP) to expose the substrate, after gap-filling the plurality of trenches 13 using the insulating material.

According to the embodiment of the present disclosure, the surface enhancement layer 52E may play the role of preventing leaning of the plurality of upper mask patterns 52M while the plurality of upper mask patterns 52M are formed (B40), the plurality of sacrificial mask patterns 46 are removed and the plurality of hard mask patterns 31HM are formed (B50). In an embodiment, the plurality of upper mask patterns 52M may be referred to as a spacer mask.

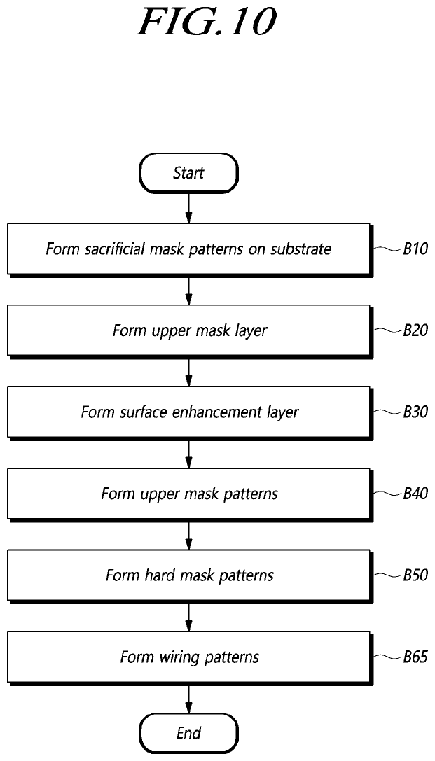

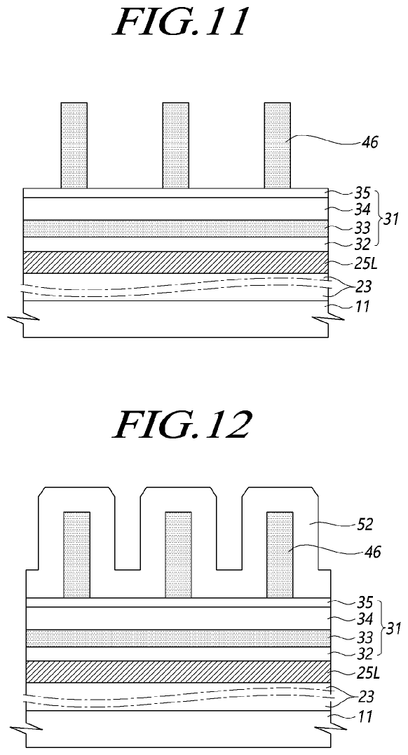

FIG. 10 is a flowchart for explaining a method of forming a semiconductor device according to an embodiment of the present disclosure, and FIGS. 11 to 18 are cross-sectional views for explaining the method of forming a semiconductor device according to the embodiment of the present disclosure.

Referring to FIG. 10, the method of forming a semiconductor device according to the embodiment of the present disclosure may include forming sacrificial mask patterns on a substrate (B10), forming an upper mask layer (B20), forming a surface enhancement layer (B30), forming upper mask patterns (B40), forming hard mask patterns (B50), and forming wiring patterns (B65). In the following, only differences will be briefly described.

Referring to FIGS. 10 and 11, an interlayer insulating layer 23 and a wiring layer 25L may be formed on a substrate 11. A hard mask layer 31 may be formed on the wiring layer 25L. A plurality of sacrificial mask patterns 46 may be formed on the hard mask layer 31 (B10). A plurality of active/passive elements may be formed in and/or on the substrate 11 and in the interlayer insulating layer 23, but will be omitted for the sake of simplicity in explanation.

The interlayer insulating layer 23 may cover the substrate 11. The interlayer insulating layer 23 may include a single layer or a multilayer. In an embodiment, the interlayer insulating layer 23 may include silicon oxide, silicon nitride, silicon oxynitride, low-K dielectric, high-K dielectric or a combination thereof. The wiring layer 25L may be formed on the interlayer insulating layer 23. The wiring layer 25L may include a single layer or a multilayer. In an embodiment, the wiring layer 25L may include a conductive material such as metal, metal oxide, metal nitride, metal silicide, polysilicon, conductive carbon or a combination thereof.

The hard mask layer 31 and the plurality of sacrificial mask patterns 46 may be formed through a method similar to that described above with reference to FIG. 2.

Referring to FIGS. 10 and 12, an upper mask layer 52 may be formed on the hard mask layer 31 and the plurality of sacrificial mask patterns 46 (B20).

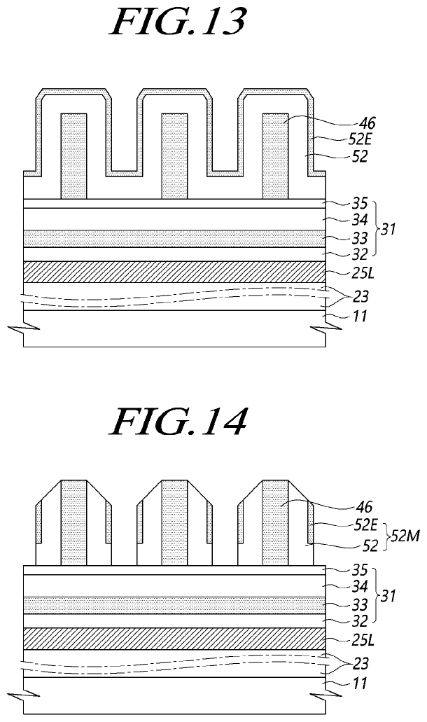

Referring to FIGS. 10 and 13, a surface enhancement layer 52E may be formed on the surface of the upper mask layer 52 (B30).

Referring to FIGS. 10 and 14, by partially removing the

surface enhancement layer 52E and the upper mask layer 52, a plurality of upper mask patterns 52M may be formed (B40).

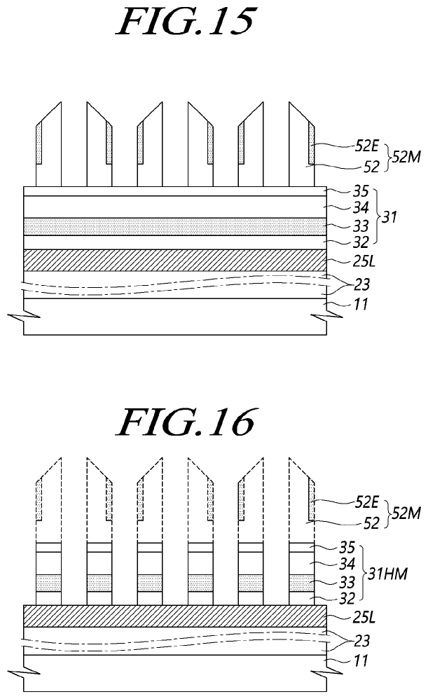

Referring to FIGS. 10 and 15, by removing the plurality of sacrificial mask patterns 46, the hard mask layer 31 may be exposed. Referring to FIGS. 10 and 16, by partially removing the hard

mask layer 31, a plurality of hard mask patterns 31HM may be formed (B50). The wiring layer 25L may be exposed between the plurality of hard mask patterns 31HM.

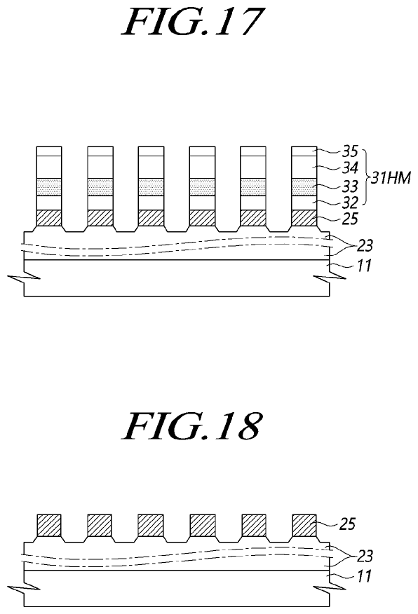

Referring to FIGS. 10 and 17, by partially removing the wiring layer 25L using the plurality of hard mask patterns 31HM as an etch mask, a plurality of wiring patterns 25 may be formed (B65). The plurality of wiring patterns 25 may be formed by performing an anisotropic etching process, an isotropic etching process or a combination thereof. The interlayer insulating layer 23 may be exposed between the plurality of wiring patterns 25.

Referring to FIGS. 10 and 18, by removing the plurality of hard mask patterns 31HM, the plurality of wiring patterns 25 may be exposed.

Although exemplary embodiments of the disclosure have been described for illustrative purposes, those skilled in the art will appreciate that various modifications, additions and substitutions are possible, without departing from the scope and spirit of the disclosure. Therefore, the embodiments disclosed above and in the accompanying drawings should be considered in a descriptive sense only and not for limiting the technological scope. The technological scope of the disclosure is not limited by the embodiments and the accompanying drawings. The spirit and scope of the disclosure should be interpreted in connection with the appended claims and encompass all equivalents falling within the scope of the appended claims.

What is claimed is:

1. A method of forming a mask pattern, the method comprising:
forming a sacrificial mask pattern on a substrate;
forming a plurality of upper mask patterns on side surfaces of the sacrificial mask pattern, each of the plurality of upper mask patterns having a surface enhancement layer and an upper mask layer between the surface enhancement layer and the sacrificial mask pattern; and
exposing the plurality of upper mask patterns by removing the sacrificial mask pattern.

2. The method according to claim 1, wherein the upper mask layer is interposed between the surface enhancement layer and the substrate.

3. The method according to claim 1, wherein:
the surface enhancement layer is formed at a level higher than a lowermost end of the upper mask layer; and
a lower surface of the surface enhancement layer contacts the upper mask layer.

4. The method according to claim 1, wherein the surface enhancement layer has a higher hardness than the upper mask layer.

5. The method according to claim 1, wherein the surface enhancement layer has a higher density than the upper mask layer.

6. The method according to claim 1, wherein the forming of the plurality of upper mask patterns comprises:
forming the upper mask layer on the substrate on which the sacrificial mask pattern is formed;
forming the surface enhancement layer on a surface of the upper mask layer; and
partially removing the surface enhancement layer and the upper mask layer to expose an upper surface of the sacrificial mask pattern.

7. The method according to claim 6, wherein the forming of the upper mask layer comprises an oxide deposition process performed at 50°° C. to 100° C.

8. The method according to claim 7, wherein the forming of the upper mask layer comprises an atomic layer deposition process.

9. The method according to claim 7, wherein the upper mask layer includes silicon oxide.

10. The method according to claim 6, wherein the forming of the surface enhancement layer comprises a rapid thermal annealing (RTA) process, a plasma treatment process or a combination thereof.

11. The method according to claim 6, wherein the forming of the surface enhancement layer comprises an RTA process performed at a temperature of 900° C. to 1100° C. for 0.001 second to 1 second.

12. The method according to claim 6, wherein the surface enhancement layer has a lesser thickness than the upper mask layer.

13. The method according to claim 6, wherein the sacrificial mask pattern includes a photoresist or a carbon-containing composition.

14. The method according to claim 6, wherein a lowermost end of the surface enhancement layer is formed at a level higher than a lowermost end of the sacrificial mask pattern.

15. The method according to claim 1, further comprising:
forming a hard mask layer on the substrate; and
forming a plurality of hard mask patterns by partially removing the hard mask layer using the plurality of upper mask patterns as an etch mask.

16. The method according to claim 15, wherein the hard mask layer comprises:
a polysilicon layer;
an amorphous carbon layer stacked on the polysilicon layer; and
a silicon oxynitride layer stacked on the amorphous carbon layer.

17. The method according to claim 16, wherein the silicon oxynitride layer has a thickness lesser than each of the polysilicon layer and the amorphous carbon layer.

18. A method of forming a semiconductor device, method comprising:
forming a hard mask layer on a substrate;
forming a sacrificial mask pattern on the hard mask layer;
forming a plurality of upper mask patterns on side surfaces of the sacrificial mask pattern, each of the plurality of upper mask patterns having a surface enhancement layer and an upper mask layer between the surface enhancement layer and the sacrificial mask pattern;
removing the sacrificial mask pattern to expose the plurality of upper mask patterns;
forming a plurality of hard mask patterns by partially removing the hard mask layer using the plurality of upper mask patterns as an etch mask;
forming a plurality of trenches which define a plurality of semiconductor patterns, in the substrate by using the plurality of hard mask patterns as an etch mask; and
forming an isolation layer in the plurality of trenches.

19. A method of forming a semiconductor device, the method comprising:
forming a wiring layer on a substrate;
forming a hard mask layer on the wiring layer;
forming a sacrificial mask pattern on the hard mask layer;
forming a plurality of upper mask patterns on side surfaces of the sacrificial mask pattern, each of the plurality of upper mask patterns having a surface enhancement layer and an upper mask layer between the surface enhancement layer and the sacrificial mask pattern;
removing the sacrificial mask pattern to expose the plurality of upper mask patterns;
forming a plurality of hard mask patterns by partially removing the hard mask layer using the plurality of upper mask patterns as an etch mask; and
forming a plurality of wiring patterns by partially removing the wiring layer using the plurality of hard mask patterns as an etch mask.
